(19) United States
(12) Patent Application Publication
(10) Pub. No.: US 2026/0317902 A1
(43) Pub. Date: Oct. 15, 2026

(54) DEPOSITION OF CONFORMAL LOW-K FILMS

(71) Applicant: Applied Materials, Inc., Santa Clara, CA (US)

(72) Inventors: Lakmal C. Kalutarage, San Jose, CA (US); Arkaprava Dan, San Jose, CA (US); Xiaopeng Yu, Santa Clara, CA (US); Kristopher Koskela, San Jose, CA (US); Seyed Mahmoud Hosseini, Sunnyvale, CA (US); Victor Fabiyi, Sunnyvale, CA (US); Austin Lee Dewyer, Sunnyvale, CA (US); Michael Haverty, Mountain View, CA (US)

(73) Assignee: Applied Materials, Inc., Santa Clara, CA (US)

(21) Appl. No.: 19/175,103

(22) Filed: Apr. 10, 2025

(51) Int. Cl. C23C 16/455; C23C 16/30; C23C 16/44; C23C 16/50

(52) U.S. Cl. CPC C23C 16/45553; C23C 16/30; C23C 16/4408; C23C 16/45536; C23C 16/50

(57) ABSTRACT

Methods for plasma enhanced atomic layer deposition (PEALD) of low-κ films are described. A method of depositing a film comprises exposing a substrate to a silicon precursor having the general formulae general formulae (I), (II), (III), (IV), (V), and (VI) wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines; and exposing the substrate to an oxidant and a plasma to react with the silicon-containing film to form a conformal low-κ film on the substrate.

### TECHNICAL FIELD

Embodiments of the present disclosure pertain to the field of semiconductor device manufacturing. More particularly, embodiments of the disclosure provide methods of depositing conformal low-κ films for logic and memory applications.

### BACKGROUND

Integrated circuits have evolved into complex devices that can include millions of transistors, capacitors, and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced, it is necessary to use low resistivity conductive materials as well as low dielectric constant insulating materials to obtain suitable electrical performance from such components.

Atomic Layer Deposition (ALD) and Plasma-Enhanced ALD (PEALD) are deposition techniques that offer control of film thickness and conformality. Most ALD processes are based on binary reaction sequences, where each of the two surface reactions occurs sequentially. Because the surface reactions are sequential, the two gas phase reactants are not in contact, and possible gas phase reactions that may form and deposit particles are limited. Due to continuously decreasing device dimensions in the semiconductor industry, there is increasing interest and applications that use ALD/PEALD.

Low-κ silicon-based dielectric films are important for the microelectronics manufacturing, e.g., as a spacer with low wet etch rate (about 0 A/min in 1:100 HF) and a k-value of less than about 3.5. Spacer applications need almost 100% conformality. ALD is known to provide conformal films due to its characteristics of self-limiting growth nature. Chemical vapor deposition (CVD) films comprising silicon (Si), carbon (C), oxygen (O), and nitrogen (N) materials are known to be able to achieve low-κ characteristics, but do not have the necessary conformality, ashing resistance, and thermal stability.

Accordingly, there is a need for new deposition methods for low-κ films.

### SUMMARY

Methods to manufacture semiconductors are described. In one or more embodiments, a method of depositing a low-κ film on a semiconductor substrate comprises: exposing the semiconductor substrate to a silicon precursor to deposit a silicon-containing film on the semiconductor substrate, the silicon precursor having a structure of general formulae (I), (II), (III), (IV), (V), and (VI):

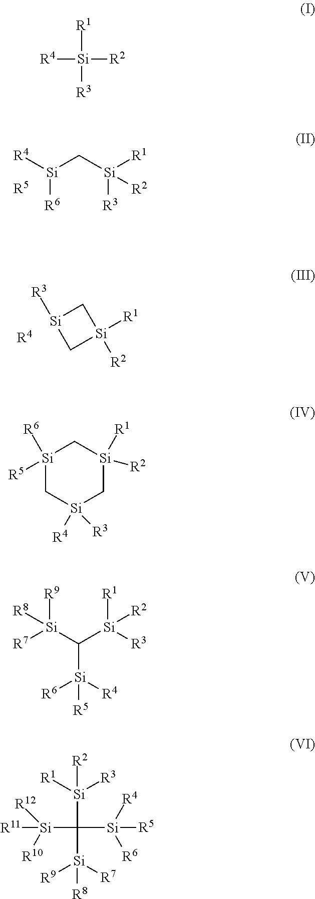

wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines; purging the semiconductor substrate of the silicon precursor; exposing the substrate to an oxidant to react with the silicon-containing film, the oxidant comprising one or more of an alcohol, a carboxylic acid, an aldehyde, a diol, a phenol, a peroxide, or ozone (O₃); purging the semiconductor substrate of the oxidant; exposing the semiconductor substrate to a plasma to form the low-κ film on the semiconductor substrate; and purging the semiconductor substrate of the plasma.

In one or more embodiments, a method of depositing a low-κ film on a semiconductor substrate comprises: exposing the semiconductor substrate to a silicon precursor to deposit a silicon-containing film on the semiconductor substrate, the silicon precursor having a structure of general formulae (I), (II), (III), (IV), (V), and (VI):

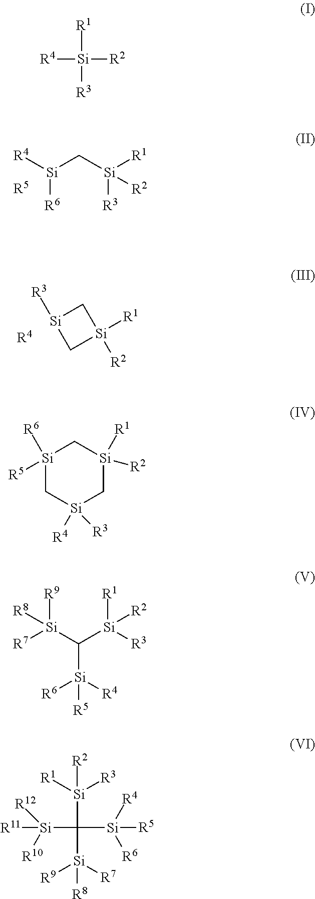

wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines; purging the semiconductor substrate of the silicon precursor; exposing the substrate to a plasma of a combination of one or more of argon (Ar), hydrogen (H₂), helium (He), nitrogen (N₂), ammonia (NH₃), hydrocarbon, and oxygen (O₂) with of an oxidant comprising one or more of an alcohol, a carboxylic acid, an aldehyde, a diol, a phenol, a peroxide, or ozone (O₃) to form the low-κ film on the semiconductor substrate; and purging the semiconductor substrate of the plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limited in the figures of the accompanying drawings in which like references indicate similar elements.

FIG. 1A illustrates a process flow diagram of a method for forming a low-κ film on a substrate in accordance with one or more embodiments;

FIG. 1B illustrates a process flow diagram of a method for forming a low-κ film on a substrate in accordance with one or more embodiments;

FIG. 1C illustrates a process flow diagram of a method for forming a low-κ film on a substrate in accordance with one or more embodiments;

FIG. 1D illustrates a process flow diagram of a method for forming a low-κ film on a substrate in accordance with one or more embodiments;

FIG. 2A illustrates a cross-section schematic representation of a semiconductor substrate being processed according to the method of one or more embodiments of the disclosure;

FIG. 2B illustrates a cross-section schematic representation of a semiconductor substrate being processed according to the method of one or more embodiments of the disclosure; and

FIG. 3 illustrates a schematic top-view diagram of an example multi-chamber processing system according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate”, “substrate surface”, or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “reactive compound,” “reactive gas,” “reactive species,” “precursor,” “process gas,” and the like are used interchangeably to mean a substance with a species capable of reacting with the substrate surface or material on the substrate surface in a surface reaction (e.g., chemisorption, oxidation, reduction). For example, a first “reactive gas” may simply adsorb onto the surface of a substrate and be available for further chemical reaction with a second reactive gas.

As used in this specification and the appended claims, the terms “precursor”, “reactant”, “reactive gas” and the like are used interchangeably to refer to any gaseous species that can react with the substrate surface.

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

As used herein, the term “dynamic random access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity.

Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions, and the body is a p region. If the MOSFET is a p-channel or pMOS FET, then the source and drain are p+ regions, and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices.

As used herein, the term “3D NAND” refers to a type of electronic (solid-state) non-volatile computer storage memory in which the memory cells are stacked in multiple layers. 3D NAND memory generally includes a plurality of memory cells that include floating-gate transistors. Traditionally, 3D NAND memory cells include a plurality of NAND memory structures arranged in three dimensions around a bit line.

Low-κ silicon-based dielectric films are very important for the microelectronics manufacturing, particularly in spacer applications for logic and memory devices. One or more embodiments provide low-κ films that can serve as spacer materials in NAND and DRAM applications, where a thin layer of material, e.g., the low-κ film, is deposited on the sidewalls of a feature. The low-κ films of one or more embodiments advantageously have a dielectric constant that is less than about 3.5, have a low wet etch rate in DHF, resistance to ashing plasma (N₂/H₂, H₂/O₂), and thermal stability greater than 500° C. The low-κ spacer films of one or more embodiments advantageously have nearly 100% conformality. As used herein, the term “conformal” means that the film or layer adapts to the contours of a feature or a layer. Conformality of a film is typically quantified by a ratio of the average thickness of a film deposited on the sidewalls of a feature to the average thickness of the same deposited layer on the field, or upper surface, of the substrate.

Atomic layer deposition (ALD) is known to provide conformal films due to its characteristics of self-limiting growth nature. Chemical vapor deposition (CVD) films comprising silicon (Si), carbon (C), oxygen (O), and nitrogen (N) materials are known to be able to achieve low-κ characteristics, but not conformality, ashing resistance, and thermal stability. In one or more embodiments, plasma enhanced atomic layer deposition (PEALD) is advantageously used to obtain good quality silicon oxycarbonitride (SiCON) films to be used as spacer materials in logic and memory applications. One or more embodiments provide methods for achieving low-κ films with high conformality, ashing resistance, and thermal stability using PEALD. Various types of precursors and processes suitable for achieving PEALD dielectric films are described herein. The precursors of one or more embodiments are designed to have the capability of attaching to a substrate using functional groups such as NR₂ and OR. In one or more embodiments, the precursors include nitrogen (N) and oxygen (O) and nitrogen (N) and oxygen (O) may be incorporated into the film. In one or more embodiments, thermal and plasma oxidizers are also described to add oxygen (O) to the film and regenerate O-containing surfaces for ALD cycles to continue.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed separately to the two or more reactive compounds which are introduced into a reaction zone of a processing chamber.

In a time-domain ALD process, exposure to each reactive compound is separated by a time delay to allow each compound to adhere and/or react on the substrate surface and then be purged from the processing chamber. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In time-domain ALD embodiments, exposure to each of the process gases are separated by a time delay/pause to allow the components of the process gases to adhere and/or react on the substrate surface. Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber, and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In one or more embodiments, the purge gas is selected from one or more of argon (Ar), nitrogen (N₂), or helium (He). In one or more embodiments, the same purge gas is used to purge the precursor and the oxidant. In other embodiments, a different purge gas is used to purge the processing chamber of the precursor than the purge gas used to purge the processing chamber of the oxidant.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In spatial ALD embodiments, exposure to each of the process gases occurs simultaneously to different parts of the substrate so that one part of the substrate is exposed to the first reactive gas while a different part of the substrate is exposed to the second reactive gas (if only two reactive gases are used). The substrate is moved relative to the gas delivery system so that each point on the substrate is sequentially exposed to both the first and second reactive gases. In any embodiment of a time-domain ALD or spatial ALD process, the sequence may be repeated until a predetermined layer thickness is formed on the substrate surface.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

Plasma enhanced atomic layer deposition (PEALD) is a widely used technique for depositing thin films on a substrate. In some examples of PEALD processes, a material may be formed from the same chemical precursors as thermal ALD processes, but at a higher deposition rate and a lower temperature. A PEALD process, in general, provides that a reactant gas and a reactant plasma are sequentially introduced into a process chamber containing a substrate. The first reactant gas is pulsed in the process chamber and is adsorbed onto the substrate surface. Thereafter, the reactant plasma is pulsed into the process chamber and reacts with the first reactant gas to form a deposition material, e.g. a thin film on a substrate. Similarly to a thermal ALD process, a purge step may be conducted between the delivery of each of the reactants. Embodiments described herein in reference to a PEALD process can be carried out using any suitable thin film deposition system. Any apparatus description described herein is illustrative and should not be construed or interpreted as limiting the scope of the embodiments described herein.

Plasma enhanced chemical vapor deposition (PECVD) is used to deposit thin films due to cost efficiency and film property versatility. In a PECVD process, for example, a hydrocarbon source, such as a gas-phase hydrocarbon or a vapor of a liquid-phase hydrocarbon that has been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

The embodiments of the disclosure are described by way of the Figures, which illustrate processes and substrates in accordance with one or more embodiments of the disclosure. The processes, schema and resulting substrates shown are merely illustrative of the disclosed processes, and the skilled artisan will recognize that the disclosed processes are not limited to the illustrated applications.

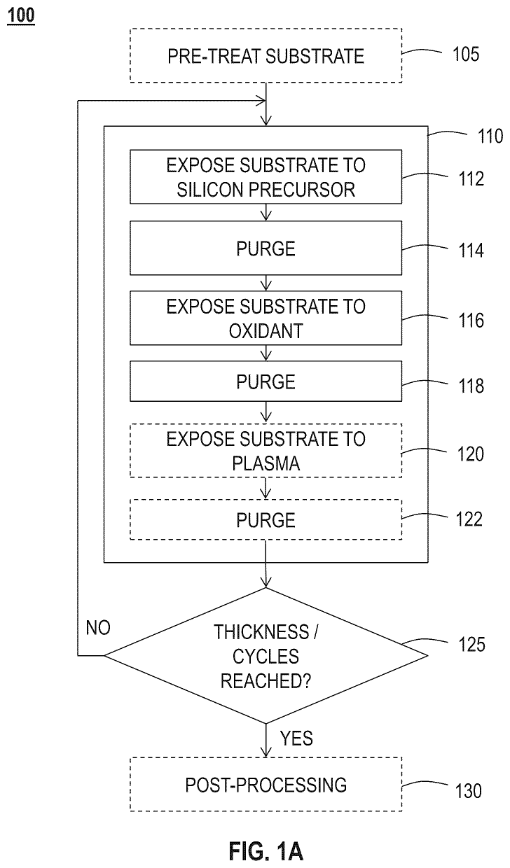

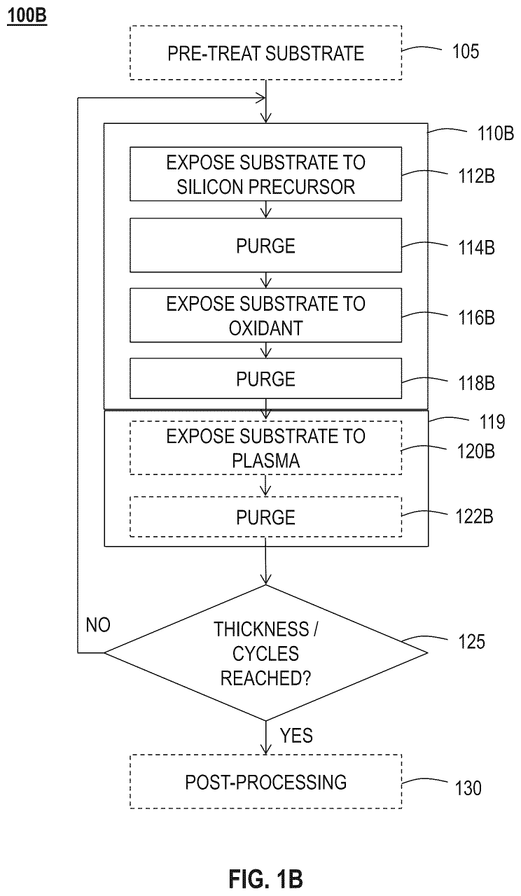

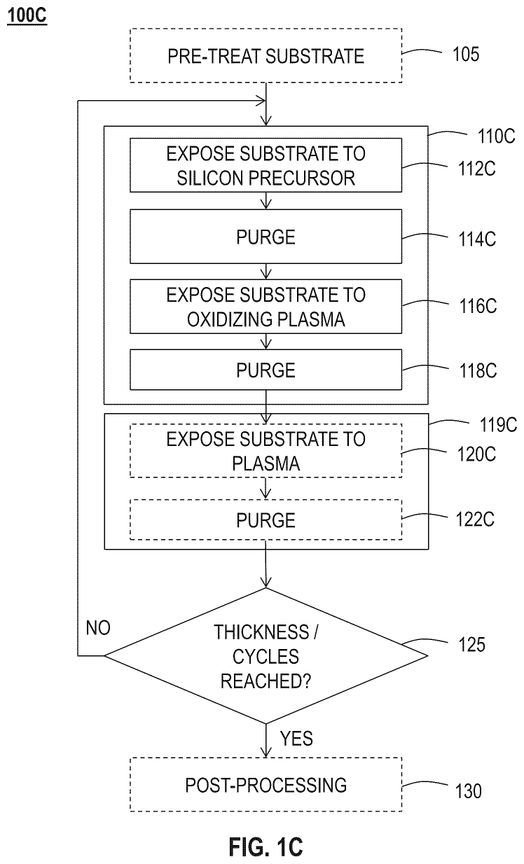

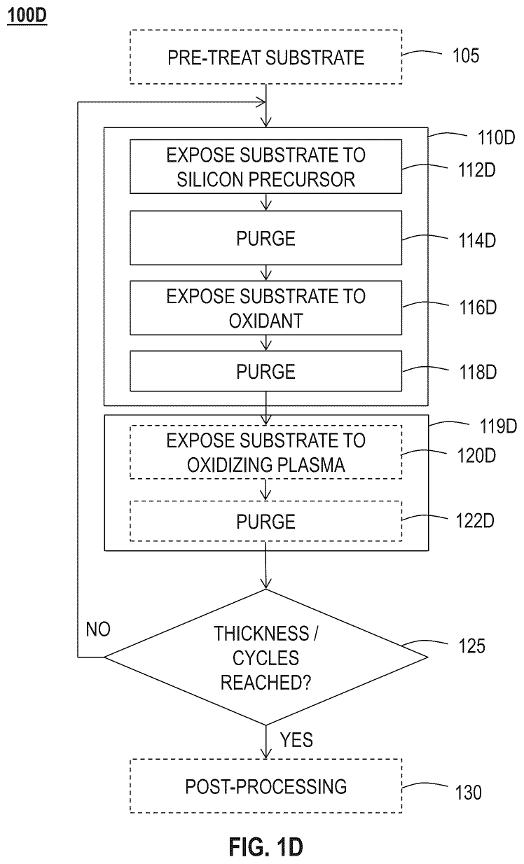

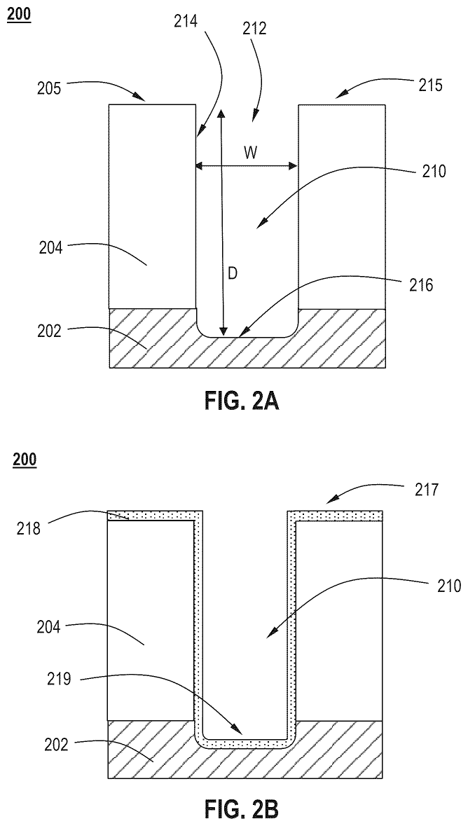

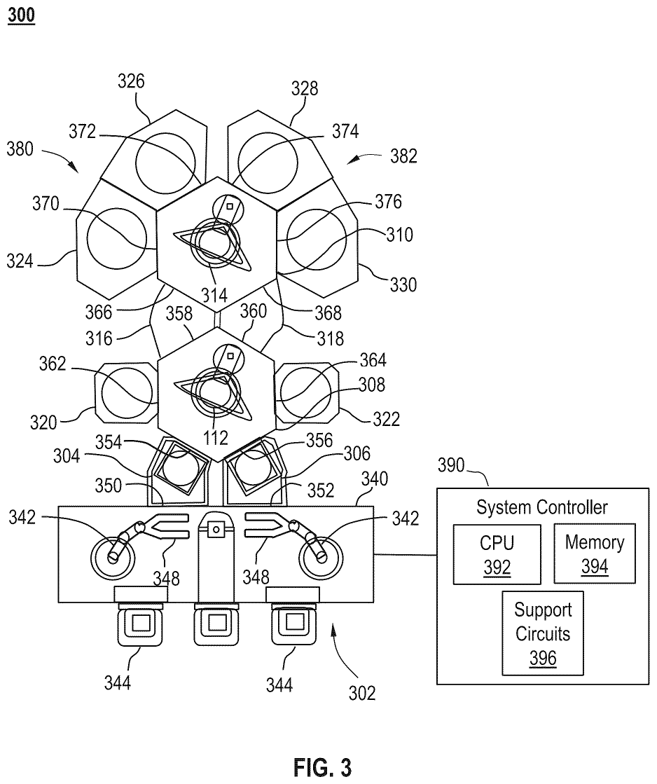

FIG. 1A illustrates a process flow diagram of a method 100 for forming a low-κ film on a substrate in accordance with one or more embodiments. FIG. 1B illustrates a process flow diagram of a method 100B for forming a low-κ film on a substrate in accordance with one or more embodiments. FIG. 1C illustrates a process flow diagram of a method 1000 for forming a low-κ film on a substrate in accordance with one or more embodiments. FIG. 1D illustrates a process flow diagram of a method 100D for forming a low-κ film on a substrate in accordance with one or more embodiments. FIGS. 2 and 3 illustrate cross-section schematic representations of a semiconductor substrate 200 being processed according to the method 100,100B,100C,100D of one or more embodiments of the disclosure.

FIG. 2A illustrates a device 200 with a substrate surface 205 formed on a substrate 202. The substrate surface refers to the exposed surface of the substrate upon which a layer may be formed.

In one or more embodiments, the device 200 has a substrate 202. In one or more embodiments, the semiconductor substrate 202 can be any suitable substrate material. In some embodiments, the substrate 202 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 202 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 202 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

In one or more embodiments, the device 200 includes a material layer 204 formed on the substrate. The material layer 204 may comprise any suitable materials known to the skilled artisan. In some embodiments, the material layer 204 may comprise a dielectric material. In other embodiments, the material layer 204 may comprise one or more conductive material, e.g., a metal. Suitable material layer 204 surfaces include, but are not limited to, silicon (Si), silicon dioxide (SiO₂), silicon oxide (SiOₓ), silicon oxycarbide (SiOC), platinum (Pt), titanium nitride (TiN), tantalum nitride (TaN), copper (Cu), cobalt (Cu), tungsten (W), ruthenium (Ru), molybdenum (Mo) or combinations thereof.

In one or more embodiments, the substrate surface 205 has at least one feature 210 formed therein. The Figures show substrates and devices having a single feature for illustrative purposes; however, those skilled in the art will understand that there can be more than one feature. The shape of the feature 210 can be any suitable shape including, but not limited to, trenches and cylindrical vias. As used in this regard, the term “feature” means any intentional surface irregularity. Suitable examples of features include, but are not limited to, trenches, which have a top, two sidewalls, and a bottom, and peaks, which have a top and two sidewalls. Features can have any suitable aspect ratio (ratio of the depth of the feature to the width of the feature). In some embodiments, the aspect ratio is greater than or equal to about 5:1, greater than or equal to about 10:1, greater than or equal to about 15:1, greater than or equal to about 20:1, greater than or equal to about 25:1, greater than or equal to about 30:1, greater than or equal to about 35:1, greater than or equal to about 40:1, greater than or equal to about 50:1, greater than or equal to about 60:1, greater than or equal to about 70:1, greater than or equal to about 80:1, greater than or equal to about 90:1, or greater than or equal to about 100:1.

In one or more embodiments, the at least one feature 210 comprises an opening between channel layers of a transistor, or memory hole, or a word line slit. Accordingly, in one or more embodiments, the device 200 comprises a memory device or a logic device, e.g., NAND, VNAND, DRAM, GAA, CFET, or the like.

In one or more embodiments, the at least one feature 210 has an opening 212 with a width W. The opening 212 is formed in a top surface 215 of the device 200. The feature 210 also has one or more sidewall 214 and extends a depth D from the top surface 215 to a bottom surface 216. While straight, vertical sidewalls are shown in the Figures, the disclosed methods may also be performed on slanted, irregular, or reentrant sidewalls.

In some embodiments, the width W of the opening 212 is greater than or equal to about 10 nm, greater than or equal to about 15 nm, greater than or equal to about 20 nm, greater than or equal to about 25 nm, greater than or equal to about 30 nm, or greater than or equal to about 35 nm. In some embodiments, the width W is in a range of about 5 nm to about 15 nm, or in a range of about 10 nm to about 35 nm.

In some embodiments, the depth D of the feature 210 is greater than or equal to about 50 nm, greater than or equal to about 75 nm, greater than or equal to about 100 nm, greater than or equal to about 150 nm, greater than or equal to about 200 nm, or greater than or equal to about 250 nm. In some embodiments, the depth D is in a range of about 100 nm to about 200 nm, or in a range of about 200 nm to about 250 nm.

Those skilled in the art will recognize the increasing challenge of depositing metal gap fill in features of narrowing width (also known as critical dimension (CD)) and/or increasing depth. The aspect ratio of the at least one feature 210 is defined as the depth D of the feature 210 divided by the width W. In some embodiments, the at least one feature has an aspect ratio (D:W) greater than or equal to about 20:1, greater than or equal to about 50:1 or greater than or equal to about 100:1.

With reference to FIG. 1A and FIG. 2B, one or more embodiments of the disclosure are directed to method 100 of depositing a thin film, e.g., a spacer film, on a semiconductor substrate. The method illustrated in FIG. 1A is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film. In some embodiments, the method comprises a plasma enhanced atomic layer deposition (PEALD process).

Referring to FIG. 2B, in one or more embodiments, a spacer film 218 is formed on the sidewall 214 and bottom surface 216 of the at least one feature 210. In one or more embodiments, the spacer film 218 may be formed on the top surface 215 of the substrate surface 205. In one or more embodiments, the spacer film 218 is a conformal layer. As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate. As used herein, a layer that is “conformally deposited” refers to a layer where the average thickness is about the same throughout. A layer which is conformal varies in thickness by less than or equal to about 5%, 2%, 1% or 0.5%. In one or more embodiments, the spacer layer 218 has a conformality greater than 90%, or greater than 91%, or greater than 92%, or greater than 93%, or greater than 94%, or greater than 95%, or greater than 96%, or greater than 97%, or greater than 98%, or greater than 99%.

The low-κ silicon-containing film, e.g., spacer film 218, may comprise any suitable material known to the skilled artisan. In one or more embodiments, the spacer film 218 comprises a silicon-containing low-κ film and is formed by the method 100 of one or more embodiments. In one or more embodiments, more than one silicon precursor, oxidant (i.e., thermal reactant), and plasma can be used in an atomic layer deposition scheme to provide the desired low-κ silicon-containing film. Depending upon the choice of silicon precursor, oxidant, and plasma, the low-κ film silicon-containing film can comprise one or more of silicon oxycarbide (SiCO), silicon oxycarbonitride (SiCON), silicon carbonitride (SiCN), silicon carbide (SiC), silicon oxide (SiOx), silicon oxynitride (SiON), and silicon nitride (SiN).

In one or more embodiments, when more than one silicon precursor, oxidant, or plasma is used, a composition gradient can be achieved. For example, if the starting film composition is silicon carbonitride (SiCN), then silicon oxycarbonitride (SiOCN) can be formed. In such instance, the silicon precursor(s), oxidant(s), and plasma(s) are selected to first deposit silicon carbonitride (SiCN), followed by formation of silicon oxycarbonitride (SiOCN). In one or more embodiments, the reason for the composition gradient is that the substrate may be incompatible with the low-κ silicon-containing film because of the presence of oxygen, so starting with a higher-κ film such as, for example, silicon carbon nitride (SiCN), which does not contain oxygen, and then depositing a film containing oxygen, e.g., silicon oxycarbonitride (SiOCN) or silicon oxycarbide (SiOC) will lead to the κ value desired. In one or more embodiments, the second layer (outer layer) may not be low-κ because integration steps that come after this film is deposited are not compatible with a low-κ film. Thus, in some embodiments, a SiCON layer is deposited first followed by deposition of a SiCN layer.

In one or more embodiments, provided is a plasma-enhanced atomic layer deposition (PEALD) process for forming low-κ films, e.g., spacer films, using organosilane precursors. In some embodiments, the silicon-containing low-κ films described herein may be formed by atomic layer deposition (plasma enhanced and/or thermal) processes using a silicon precursor including one or more precursor of general formulae (I), (II), (III), (IV), (V), and (VI), as described herein. In some embodiments, the silicon precursor comprises one or more precursor of general formulae (I), (II), (III), (IV), (V), and (VI). In other embodiments, the silicon precursor consists essentially of one or more precursor of general formulae (I), (II), (III), (IV), (V), and (VI). As used in this manner, the term “consists essentially of” means that the silicon precursor has greater than or equal to about 95%, 98%, 99% or 99.5% of one or more precursor of general formulae (I), (II), (III), (IV), (V), and (VI) on a molecular basis. The presence of diluent, carrier and/or inert gases, for example, is not taken into consideration in the calculation.

Referring to FIG. 1A, in one or more embodiments, the method 100 may include a pre-treatment operation 105. The pre-treatment can be any suitable pre-treatment known to the skilled artisan. Suitable pre-treatments include, but are not limited to, pre-heating, cleaning, soaking, native oxide removal, or deposition of an adhesion layer (e.g. C-containing film). In one or more embodiments, an adhesion layer, such as titanium nitride, is deposited at pre-treatment operation 105.

At deposition operation 110, a process is performed to deposit a silicon-containing thin film on the substrate (or substrate surface). The deposition process can include one or more operations to form a film on the substrate. In operation 112, the substrate (or substrate surface) is exposed to a silicon precursor to deposit a film on the substrate (or substrate surface).

In one or more embodiments, the silicon precursors are of general formulae (I), (II), (III), (IV), (V), and (VI):

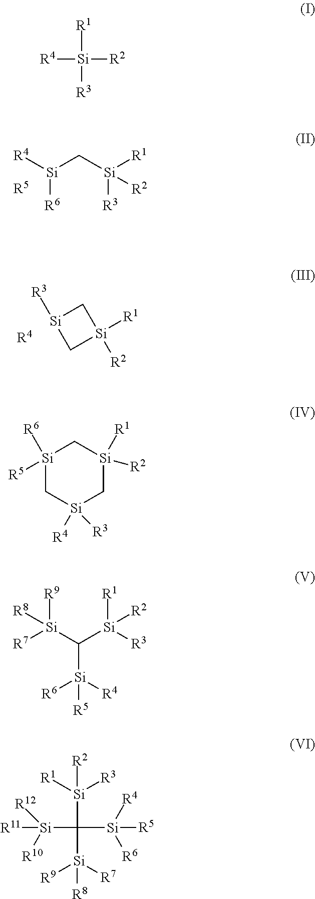

wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines.

Unless otherwise indicated, the term “lower alkyl,” “alkyl,” or “alk” as used herein alone or as part of another group includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

As used herein, the term “alkoxy” includes any of the above alkyl groups linked to an oxygen atom. The alkoxy may be substituted or unsubstituted.

As used herein, the terms “vinyl” or “vinyl-containing” refer to groups containing the vinyl group (—CH═CH₂). The vinyl may be substituted or unsubstituted, linear or branched.

As used herein, the term “amine” relates to any organic compound containing at least one basic nitrogen atom, e.g., NR′₂, wherein R′ is independently selected from hydrogen (H) or alkyl. The alkyl of the amine may be substituted or unsubstituted, linear or branched. In some embodiments, the alkyl of the amine contains from 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like.

As used herein, the term “silane” refers to a compound SiR′₃, wherein R′ is independently selected from hydrogen (H) or alkyl. The alkyl of the silane may be substituted or unsubstituted, linear or branched. In some embodiments, the alkyl of the silane contains from 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like.

The deposition process 110 may be carried out at temperatures ranging from about 100° C. to about 650° C., or ranging from about 100° C. to about 550° C. including about 225° C., about 250° C., about 275° C., about 300° C., about 325° C., about 350° C., about 375° C., about 400° C., about 425° C., about 450° C., about 475° C., about 500° C., about 525° C., about 550° C., about 575° C., about 600° C., about 625° C., and about 650° C.

The deposition process 110 may be carried out in a process volume at pressures ranging from 0.1 mTorr to 500 Torr, including pressures in a range of from 50 mTorr to 50 Torr, including a pressure of about 0.1 mTorr, about 10 mTorr, about 100 mTorr, about 1000 mTorr, about 5000 mTorr, about 10 Torr, about 20 Torr, about 30 Torr, about 40 Torr, about 50 Torr, about 60 Torr, about 70 Torr, about 80 Torr, about 90 Torr, about 100 Torr, about 150 Torr, about 200 Torr, about 250 Torr, about 300 Torr, about 350 Torr, about 400 Torr, about 350 Torr, and about 500 Torr.

The deposition process 110 may be carried out with a gas flow rate in a range of from about 100 sccm to about 10,000 sccm, including a gas flow rate of about 100 sccm, about 500 sccm, about 1000 sccm, about 1500 sccm, about 2000 sccm, about 2500 sccm, about 3000 sccm, about 3500 sccm, about 4000 sccm, about 4500 sccm, about 5000 sccm, about 5500 sccm, about 6000 sccm, about 6500 sccm, about 7000 sccm, about 7500 sccm, about 8000 sccm, about 8500 sccm, about 9000 sccm, about 9500 sccm, and about 10,000 sccm.

In one or more embodiments, the silicon precursor is flowed into the processing chamber as a gas. In one or more embodiments, the precursor-containing gas further includes one or more of a dilution gas selected from helium (He), argon (Ar), xenon (Xe), nitrogen (N₂), or hydrogen (H₂). The dilution gas of some embodiments comprises a compound that is inert gas relative to the reactants and substrate materials.

At operation 114, the processing chamber is purged to remove unreacted silicon precursor, reaction products and by-products. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the silicon precursor by any suitable technique including, but not limited to, moving the substrate through a gas curtain to a portion or sector of the processing chamber that contains none or substantially none of the silicon precursor. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur.

At operation 116, the substrate (or substrate surface) is exposed to an oxidizing agent (or oxidant) to form one or more of a silicon oxycarbide (SiOC) or silicon oxycarbonitride (SiOCN) film on the substrate. The oxidizing agent can react with the silicon-containing species (e.g. silicon-containing film) on the substrate surface to form one or more of a silicon oxycarbide (SiOC) or silicon oxycarbonitride (SiOCN) film.

In some embodiments, the oxidizing agent comprises one or more of an alcohol, a carboxylic acid, an aldehyde, a diol, a phenol, a peroxide, or ozone. In some embodiments, the oxidizing agent comprises or consists essentially of one or more of ozone (O₃) or a structure of general formulae (A), (B), (C), (D), (E), and (F):

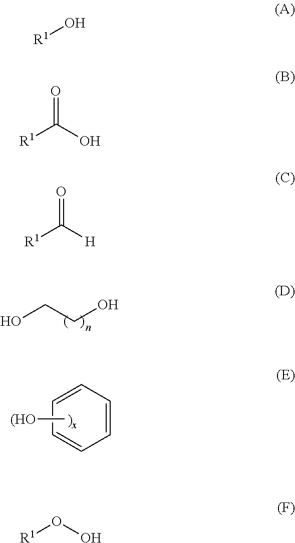

wherein R¹ is independently selected from hydrogen (H), substituted or unsubstituted linear alkyl, substituted or unsubstituted branched alkyl, substituted or unsubstituted linear alkoxy, substituted or unsubstituted branched alkoxy, substituted or unsubstituted vinyl, substituted or unsubstituted linear alkyl amines, and substituted or unsubstituted branched alkyl amines, n is an integer from −1 to 6, and x is an integer from 1 to 3.

At operation 118, the processing chamber is purged after exposure to the oxidizing agent. Purging the processing chamber in operation 118 can be the same process or different process than the purge in operation 114. Purging the processing chamber, portion of the processing chamber, area adjacent the substrate surface, etc., removes unreacted oxidizing agent, reaction products and by-products from the area adjacent the substrate surface.

In one or more embodiments, the deposition process comprises a plasma enhanced atomic layer deposition process (PEALD). After forming silicon oxycarbide (SiOC) or silicon oxycarbonitride (SiOCN) film on the substrate, the substrate is exposed to a plasma at operation 120. In one or more embodiments, the plasma is selected from one or more of argon (Ar), hydrogen (H₂), helium (He), nitrogen (N₂), ammonia (NH₃), hydrocarbon, and oxygen (O₂).

In one or more embodiments, exposing the silicon oxycarbide (SiOC) or silicon oxycarbonitride (SiOCN) film to a plasma in the processing chamber improves the growth rate and helps maintain a high carbon content in the silicon oxycarbide (SiOC) or silicon oxycarbonitride (SiOCN) film. In some embodiments, the plasma is a remote plasma. In other embodiments, the plasma is a direct plasma.

In one or more embodiments, the plasma may be generated remotely or within the processing chamber. In one or more embodiments, the plasma is an inductively coupled plasma (ICP) or a conductively coupled plasma (CCP). In other embodiments, the plasma is a direct microwave plasma or a remote microwave plasma.

Any suitable power can be used depending on, for example, the reactants, or the other process conditions. In some embodiments, the plasma is generated with a plasma power in the range of about 10 W to about 3000 W. In some embodiments, the plasma is generated with a plasma power less than or equal to about 3000 W, less than or equal to about 2000 W, less than or equal to about 1000 W, less than or equal to about 500 W, or less than or equal to about 250 W.

At operation 122, the processing chamber is purged after exposure to the plasma. Purging the processing chamber in operation 122 can be the same process or different process than the purge in operation 114 and/or operation 118. Purging the processing chamber, portion of the processing chamber, area adjacent the substrate surface, etc., removes the strong oxidant, plasma, reaction products and by-products from the area adjacent the substrate surface.

At decision 125, the thickness of the deposited film, or number of cycles of silicon-precursor and oxidizing agent is considered. If the deposited film has reached a predetermined thickness or a predetermined number of process cycles have been performed, the method 100 moves to a post-processing operation 130. If the thickness of the deposited film or the number of process cycles has not reached the predetermined threshold, the method 100 returns to deposition operation 110 to expose the substrate surface to the silicon precursor again in operation 112 and continuing.

In one or more embodiments, the low-κ spacer film 218 may be deposited to a thickness greater than about 0.1 nm. In other embodiments, the low-κ spacer film 218 may be deposited to a thickness in a range of about 0.1 nm to about 100 nm, or about 0.5 nm to about 100 nm, including about 0.1 nm, about 1 nm, about 10 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, or about 100 nm.

In one or more embodiments, the low-κ spacer film 218 advantageously has a wet etch rate (WER) in range of about 0.1 Å/min to about 10 Å/min in hydrofluoric acid (1:100 HF), including about 0.1 Å/min, about 0.5 Å/min, about 1 Å/min, about 2 Å/min, about 3 Å/min, about 4 Å/min, about 5 Å/min, about 6 Å/min, about 7 Å/min, about 8 Å/min, about 9 Å/min, and about 10 Å/min. The low-κ spacer film 218 of one or more embodiments, advantageously has high ashing resistance. In one or more embodiments, the low-κ spacer film 218 has a dielectric constant or extinction coefficient or k-value in a range of about 3.5 to about 6.0, including about 3.5, about 3.75, about 4.0, about 4.25, about 4.5, about 4.75, about 5.0, about 5.25, about 5.5, about 5.75, or about 6.0.

In one or more embodiments, the density of the low-κ spacer film 218 is greater than about 2.1 g/cc.

Referring to FIG. 1A, the post-processing operation 130 can be, for example, a process to modify film properties (e.g., annealing) or a further film deposition process (e.g., additional ALD or CVD processes) to grow additional films. In some embodiments, the post-processing operation 130 can be a process that modifies a property of the deposited film. In some embodiments, the post-processing operation 130 comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

The method 100 can be performed at any suitable temperature depending on, for example, the silicon precursor, oxidizing agent or thermal budget of the device. In some embodiments, exposures to the silicon precursor (operation 112) and the oxidizing agent (operation 116) occur at the same temperature. In some embodiments, the substrate is maintained at a temperature in a range of about 100° C. to about 650° C., or in the range of about 100° C. to about 550° C.

In some embodiments, exposure to the silicon precursor (operation 112) occurs at a different temperature than the exposure to the oxidizing agent (operation 116). In some embodiments, the substrate is maintained at a first temperature in a range of about 100° C. to about 550° C. for the exposure to the silicon precursor, and at a second temperature in the range of about 100° C. to about 550° C. for exposure the oxidizing agent.

In the embodiment illustrated in FIG. 1A, deposition operation 110 the substrate (or substrate surface) is exposed to the silicon precursor, the oxidizing agent, and the plasma sequentially. In another, un-illustrated, embodiment, the substrate (or substrate surface) is exposed to the silicon precursor, the oxidizing agent, and the plasma simultaneously in a CVD reaction. In a CVD reaction, the substrate (or substrate surface) can be exposed to a gaseous mixture of the silicon precursor, oxidizing agent, and plasma to deposit one or more of a silicon oxycarbide (SiOC) or silicon oxycarbonitride (SiOCN) film having a predetermined thickness. In the CVD reaction, one or more of a silicon oxycarbide (SiOC) or silicon oxycarbonitride (SiOCN) film can be deposited in one exposure to the mixed reactive gas, or can be multiple exposures to the mixed reactive gas with purges between.

In one or more embodiments, any suitable combination of operations are within the present disclosure. For example, in one or more embodiments, the method 100 may include exposure of the substrate (or substrate surface) to the silicon precursor (at operation 112), a purge (operation 114), exposure to the oxidant (operation 116), a purge (operation 118), exposure to the plasma (operation 120), followed by exposure to the silicon precursor (operation 112) again.

In one or more embodiments, as illustrated in FIG. 1B, the method 100B may include a first deposition cycle 110B and a second deposition cycle 119. In deposition cycle 110B, the substrate (or substrate surface) is exposed to the silicon precursor (at operation 112B), purge (operation 114B), the oxidant (operation 116B), and purge (operation 118B) in a cycle 110B that can be repeated from 1 to 1000 times. The substrate surface is then exposed to the plasma (operation 120B) and a purge (operation 122B) in a second cycle 119 that can be repeated from 1 to 1000 times.

With reference to FIG. 1C, the method 100C may include a first deposition cycle 110C and a second deposition cycle 119C. In deposition cycle 110C, the substrate (or substrate surface) is exposed to the silicon precursor (at operation 112C), purge (operation 114C), and oxidizing plasma (operation 116C), and purge (operation 118C) in a cycle 110C that can be repeated from 1 to 1000 times. The substrate surface is then exposed to the plasma (operation 120C) and a purge (operation 122C) in a second cycle 119C that can be repeated from 1 to 1000 times.

At operation 116C, the substrate (or substrate surface) is exposed to an oxidizing plasma to form one or more of a silicon oxycarbide (SiOC) or silicon oxycarbonitride (SiOCN) film on the substrate. The oxidizing plasma can react with the silicon-containing species (e.g. silicon-containing film) on the substrate surface to form one or more of a silicon oxycarbide (SiOC) or silicon oxycarbonitride (SiOCN) film.

In some embodiments, the oxidizing plasma comprises a plasma of a combination of one or more of argon (Ar), hydrogen (H₂), helium (He), nitrogen (N₂), ammonia (NH₃), hydrocarbon, and oxygen (O₂) with one or more oxidant selected from the group consisting of an alcohol, a carboxylic acid, an aldehyde, a diol, a phenol, a peroxide, or ozone. In some embodiments, the oxidant comprises or consists essentially of one or more of ozone (O₃) or a structure of general formulae (A), (B), (C), (D), (E), and (F):

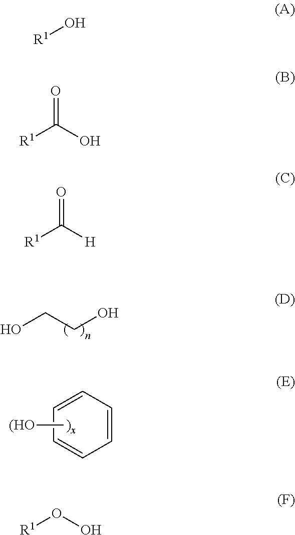

wherein R¹ is independently selected from hydrogen (H), substituted or unsubstituted linear alkyl, substituted or unsubstituted branched alkyl, substituted or unsubstituted linear alkoxy, substituted or unsubstituted branched alkoxy, substituted or unsubstituted vinyl, substituted or unsubstituted linear alkyl amines, and substituted or unsubstituted branched alkyl amines, n is an integer from −1 to 6, and x is an integer from 1 to 3.

In yet further embodiments, the method 1000 may include exposure of the substrate (or substrate surface) to the silicon precursor (at operation 112C), a purge (operation 114C), exposure to the oxidizing plasma (operation 116C), followed by exposure to the silicon precursor (operation 112C) again.

With reference to FIG. 1D, the method 100D may include a first deposition cycle 110D and a second deposition cycle 119D. In first deposition cycle 110D, the substrate (or substrate surface) is exposed to the silicon precursor (at operation 112D), purge (operation 114D), an oxidant (operation 116D), and purge (operation 118D) in a cycle 110D that can be repeated from 1 to 1000 times. The substrate surface is then exposed to an oxidizing plasma (operation 120D) and a purge (operation 122D) in a second cycle 119D that can be repeated from 1 to 1000 times.

At operation 120D, the substrate (or substrate surface) is exposed to an oxidizing plasma to form one or more of a silicon oxycarbide (SiOC) or silicon oxycarbonitride (SiOCN) film on the substrate. The oxidizing plasma can react with the silicon-containing species (e.g. silicon-containing film) on the substrate surface to form one or more of a silicon oxycarbide (SiOC) or silicon oxycarbonitride (SiOCN) film.

In some embodiments, the oxidizing plasma comprises a plasma of a combination of one or more of argon (Ar), hydrogen (H₂), helium (He), nitrogen (N₂), ammonia (NH₃), hydrocarbon, and oxygen (O₂) with one or more oxidant selected from the group consisting of an alcohol, a carboxylic acid, an aldehyde, a diol, a phenol, a peroxide, or ozone. In some embodiments, the oxidant comprises or consists essentially of one or more of ozone (O₃) or a structure of general formulae (A), (B), (C), (D), (E), and (F):

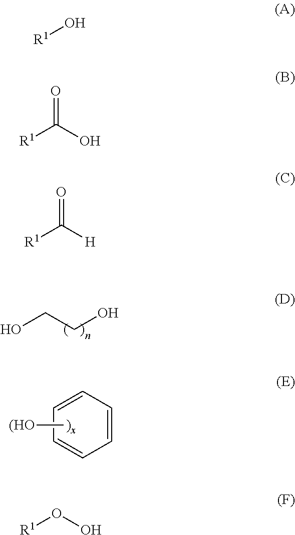

wherein R¹ is independently selected from hydrogen (H), substituted or unsubstituted linear alkyl, substituted or unsubstituted branched alkyl, substituted or unsubstituted linear alkoxy, substituted or unsubstituted branched alkoxy, substituted or unsubstituted vinyl, substituted or unsubstituted linear alkyl amines, and substituted or unsubstituted branched alkyl amines, n is an integer from −1 to 6, and x is an integer from 1 to 3.

In one or more embodiments, any suitable combination of operations are within the present disclosure. For example, in one or more embodiments, the method 100D may include exposure of the substrate (or substrate surface) to the silicon precursor (at operation 112D), a purge (operation 114D), exposure to the oxidant (operation 116D), a purge (operation 118D), exposure to the oxidizing plasma (operation 120D), followed by exposure to the silicon precursor (operation 112D) again.

In one or more embodiments, the low-κ silicon-containing film has a carbon content of greater than or equal to about 5%, 7.5%, 10%, 12.5 or 15%, on an atomic basis. In some embodiments, the low-κ silicon-containing film comprises silicon oxycarbide (SiOC). In some embodiments, the silicon oxycarbide (SiOC) film comprises a carbon content in the range of about 2% to about 50%, or in the range of about 3% to about 45%, or in the range of about 4% to about 40%, on an atomic basis. In some embodiments, the silicon oxycarbide (SiOC) film has no nitrogen present.

In one or more embodiments, the low-κ silicon-containing film comprises silicon oxycarbonitride (SiOCN). In one or more embodiments, the silicon oxycarbonitride (SiOCN) film has a nitrogen content of greater than or equal to about 0%, 5%, 7.5%, 10%, 12.5 or 15%, on an atomic basis. In some embodiments, the silicon oxycarbonitride (SiOCN) film comprises a nitrogen content in the range of about 0% to about 40%, or in the range of about 3% to about 35%, or in the range of about 4% to about 30%, on an atomic basis.

The deposition operation 110 can be repeated to form a low-κ silicon-containing film having a predetermined thickness. In some embodiments, the deposition operation 110 is repeated to provide a low-κ silicon-containing film having a thickness greater than about 0.1 nm, or in the range of about 0.1 nm to about 1000 nm.

In one or more embodiments, the low-κ silicon oxycarbide (SiOC) film or silicon oxycarbonitride (SiOCN) film is used as a spacer film.

According to one or more embodiments, the substrate is subjected to processing prior to and/or after forming the low-κ silicon-containing film. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers and then moved to the separate processing chamber. Accordingly, the processing apparatus may comprise multiple chambers in communication with a transfer station. An apparatus of this sort may be referred to as a “cluster tool” or “clustered system,” and the like.

In one or more embodiments, the substrate is moved from a first chamber to a separate, next chamber for further processing, e.g., at optional operation 130. The substrate can be moved directly from the first chamber to the separate processing chamber, or the substrate can be moved from the first chamber to one or more transfer chambers and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. FIG. 3 is a schematic top-view diagram of an exemplary multi-chamber processing system 300 according to one or more embodiments of the present disclosure. The processing system 300 generally includes a factory interface 302, load lock chambers 304, 306, transfer chambers 308, 310 with respective transfer robots 312, 314, holding chambers 316, 318, and processing chambers 320, 322, 324, 326, 328, 330. As detailed herein, wafers in the processing system 300 can be processed in and transferred between the various chambers without exposing the wafers to an ambient environment exterior to the processing system 300 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 300. Accordingly, the processing system 300 may provide for an integrated solution for some processing of wafers.

In the illustrated example of FIG. 3, the factory interface 302 includes a docking station 340 and factory interface robots 342 to facilitate transfer of wafers. The docking station 340 is configured to accept one or more front opening unified pods (FOUPs) 344. In some examples, each factory interface robot 342 generally comprises a blade 348 disposed on one end of the respective factory interface robot 342 configured to transfer the wafers from the factory interface 302 to the load lock chambers 304, 306.

The load lock chambers 304, 306 have respective ports 350, 352 coupled to the factory interface 302 and respective ports 354, 356 coupled to the transfer chamber 308. The transfer chamber 308 further has respective ports 358, 360 coupled to the holding chambers 316, 318 and respective ports 362, 364 coupled to processing chambers 320, 322. Similarly, the transfer chamber 310 has respective ports 366, 368 coupled to the holding chambers 316, 318 and respective ports 370, 372, 374, 376 coupled to processing chambers 324, 326, 328, 330. The ports 354, 356, 358, 360, 362, 364, 366, 368, 370, 372, 374, 376 can be, for example, slit valve openings with slit valves for passing wafers therethrough by the transfer robots 312, 314 and for providing a seal between respective chambers to prevent a gas from passing between the respective chambers. Generally, any port is open for transferring a wafer therethrough. Otherwise, the port is closed.

The load lock chambers 304, 306, transfer chambers 308, 310, holding chambers 316, 318, and processing chambers 320, 322, 324, 326, 328, 330 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 342 transfers a wafer from a FOUP 344 through a port 350 or 352 to a load lock chamber 304 or 306. The gas and pressure control system then pumps down the load lock chamber 304 or 306. The gas and pressure control system further maintains the transfer chambers 308, 310 and holding chambers 316, 318 with an interior low pressure or vacuum environment (which may include an inert gas). Hence, the pumping down of the load lock chamber 304 or 306 facilitates passing the wafer between, for example, the atmospheric environment of the factory interface 302 and the low pressure or vacuum environment of the transfer chamber 308.

With the wafer in the load lock chamber 304 or 306 that has been pumped down, the transfer robot 312 transfers the wafer from the load lock chamber 304 or 306 into the transfer chamber 308 through the port 354 or 356. The transfer robot 312 is then capable of transferring the wafer to and/or between any of the processing chambers 320, 322 through the respective ports 362, 364 for processing and the holding chambers 316, 318 through the respective ports 358, 360 for holding to await further transfer. Similarly, the transfer robot 314 is capable of accessing the wafer in the holding chamber 316 or 318 through the port 366 or 368 and is capable of transferring the wafer to and/or between any of the processing chambers 324, 326, 328, 330 through the respective ports 370, 372, 374, 376 for processing and the holding chambers 316, 318 through the respective ports 366, 368 for holding to await further transfer. The transfer and holding of the wafer within and among the various chambers can be in the low pressure or vacuum environment provided by the gas and pressure control system.

The processing chambers 320, 322, 324, 326, 328, 330 can be any appropriate chamber for processing a wafer. In some embodiments, the processing chamber 320 can be capable of performing an annealing process, the processing chamber 322 can be capable of performing a cleaning process, and the processing chambers 324, 326, 328, 330 can be capable of performing epitaxial growth processes. In some examples, the processing chamber 322 can be capable of performing a cleaning process, the processing chamber 320 can be capable of performing an etch process, and the processing chambers 324, 326, 328, 330 can be capable of performing respective epitaxial growth processes. The processing chamber 322 may be any suitable preclean chamber known to the skilled artisan. The processing chamber 320 may be any suitable etch chamber known to the skilled artisan.

A system controller 390 is coupled to the processing system 300 for controlling the processing system 300 or components thereof. For example, the system controller 390 may control the operation of the processing system 300 using a direct control of the chambers 304, 306, 308, 316, 318, 310, 320, 322, 324, 326, 328, 330 of the processing system 300 or by controlling controllers associated with the chambers 304, 306, 308, 316, 318, 310, 320, 322, 324, 326, 328, 330. In operation, the system controller 390 enables data collection and feedback from the respective chambers to coordinate performance of the processing system 300.

The system controller 390 generally includes a central processing unit (CPU) 392, memory 394, and support circuits 396. The CPU 392 may be one of any form of a general-purpose processor that can be used in an industrial setting. The memory 394, or non-transitory computer-readable medium, is accessible by the CPU 392 and may be one or more of memory such as random-access memory (RAM), read only memory (ROM), floppy disk, hard disk, or any other form of digital storage, local or remote. The support circuits 396 are coupled to the CPU 392 and may comprise cache, clock circuits, input/output subsystems, power supplies, and the like. The various methods disclosed herein may generally be implemented under the control of the CPU 392 by the CPU 392 executing computer instruction code stored in the memory 394 (or in memory of a particular process chamber) as, for example, a software routine. When the computer instruction code is executed by the CPU 392, the CPU 392 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 308, 310 and the holding chambers 316, 318. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 390 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general-purpose computer into a specific-purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes a processing chamber to perform the operations of any of the methods (e.g., method 100) described herein. In one or more embodiments, the controller causes a processing chamber to perform the operations of method 100. In one or more embodiments, the controller causes the processing chamber to perform the operations of depositing a low-κ silicon-containing film on a substrate surface having at least one feature therein (operation 110). The at least one feature comprises at least one surface defining a via having a bottom surface and at least one sidewall. In one or more embodiments, the controller causes the processing chamber to perform the operations of exposing to a silicon precursor, an oxidant, and a plasma to form a low-κ silicon-containing film.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Deposition of Silicon-Containing Spacer Layer

General Procedure: The semiconductor substrate was exposed to a silicon precursor carried in an atmosphere of Ar gas for about 3 seconds. Excess silicon precursor and byproducts were removed from the chamber by purging for 20 seconds. The semiconductor substrate was then exposed to an oxidant and a plasma to form a low-κ film on the semiconductor substrate. The deposition occurred at a temperature in a range of from 100° to 550° C.

Table 1 shows the results of the different combinations of silicon precursor, oxidant, and plasma on the composition of the low-κ film and properties of the low-κ film.

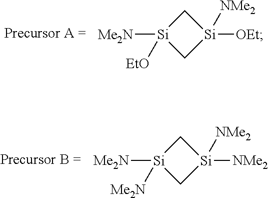 [SMILES: CCO[Si]1(N(C)C)C[Si](OCC)(N(C)C)C1 ; CN(C)[Si]1(N(C)C)C[Si](N(C)C)(N(C)C)C1]

Plasma A=Argon (Ar); Plasma B=Argon/Hydrogen (Ar/H₂)
Oxidant A=water; Oxidant B=acetic acid

TABLE 1

| | | Dielectric | Wet Etch |
|---|---|---|---|
| | Composition | Constant | Rate |
| ALD Scheme | (Si, C, N, O) | (κ value) | in DHF |
| Precursor A | 35.6, 13.0, | 3.95 | 3.3 |
| Plasma A | 13.4, 37.9 | | |
| Precursor A | 42.9, 30.5, | 6.02 | 0.7 |
| Plasma B | 6.9, 19.6 | | |
| Precursor A | 36.3, 6.8, | 3.68 | 0.5 |
| Oxidant A | 2.4, 54.4 | | |
| Plasma B | | | |
| Precursor A | 37.5, 16.9, | — | 0.7 |
| Oxidant B | 3.0, 42.5 | | |
| Plasma B | | | |
| Precursor B | 44.7, 37.9, | — | 2.0 |
| Oxidant B | 3.5, 13.9 | | |
| Plasma B | | | |

Conclusion: Various k values and wet etch rates can be obtained by changing precursor, oxidant, and plasma.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of depositing a low-κ film on a semiconductor substrate, the method comprising:
exposing the semiconductor substrate to a silicon precursor to deposit a silicon-containing film on the semiconductor substrate, the silicon precursor having a structure of general formulae (I), (II), (III), (IV), (V), and (VI): 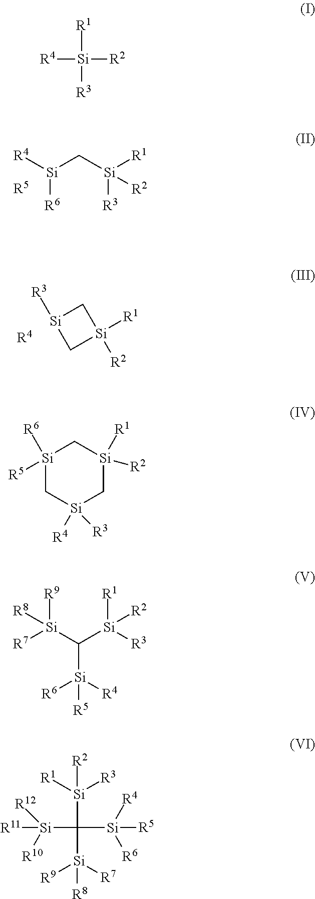
wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines;
purging the semiconductor substrate of the silicon precursor;
exposing the substrate to an oxidant to react with the silicon-containing film, the oxidant comprising one or more of an alcohol, a carboxylic acid, an aldehyde, a diol, a phenol, a peroxide, or ozone (O₃);
purging the semiconductor substrate of the oxidant;
exposing the semiconductor substrate to a plasma to form the low-κ film on the semiconductor substrate; and
purging the semiconductor substrate of the plasma.

2. The method of claim 1, wherein the plasma comprises one or more of argon (Ar), hydrogen (H₂), helium (He), nitrogen (N₂), ammonia (NH₃), hydrocarbon, and oxygen (O₂).

3. The method of claim 1, wherein the plasma is selected from a remote plasma and a direct plasma.

4. The method of claim 1, wherein the oxidant comprises ozone (O₃) or a general formulae (A), (B), (C), (D), (E), and (F): 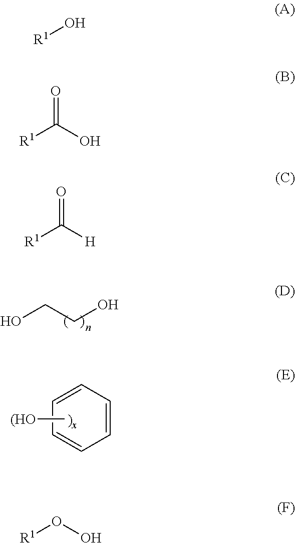
wherein R¹ is independently selected from hydrogen (H), substituted or unsubstituted linear alkyl, substituted or unsubstituted branched alkyl, substituted or unsubstituted linear alkoxy, substituted or unsubstituted branched alkoxy, substituted or unsubstituted vinyl, substituted or unsubstituted linear alkyl amines, and substituted or unsubstituted branched alkyl amines, n is an integer from −1 to 6, and x is an integer from 1 to 3.

5. The method of claim 1, wherein the low-κ film comprises one or more of silicon oxycarbide (SiCO), silicon oxycarbonitride (SiCON), silicon carbonitride (SiCN), silicon carbide (SiC), silicon oxide (SiOx), silicon oxynitride (SiON), and silicon nitride (SiN).

6. The method of claim 1, wherein the low-κ film has a K-value of greater than 3.5.

7. The method of claim 1, wherein the low-κ film has a conformality of greater than 90%.

8. The method of claim 1, wherein purging the semiconductor substrate comprises flowing a purge gas over the semiconductor substrate.

9. The method of claim 8, wherein the purge gas is selected from one or more of argon (Ar), nitrogen (N₂), or helium (He).

10. The method of claim 1, wherein the low-κ film has a thickness greater than about 0.1 nm.

11. A method of depositing a low-κ film on a semiconductor substrate, the method comprising:
exposing the semiconductor substrate to a silicon precursor to deposit a silicon-containing film on the semiconductor substrate, the silicon precursor having a structure of general formulae (I), (II), (III), (IV), (V), and (VI): 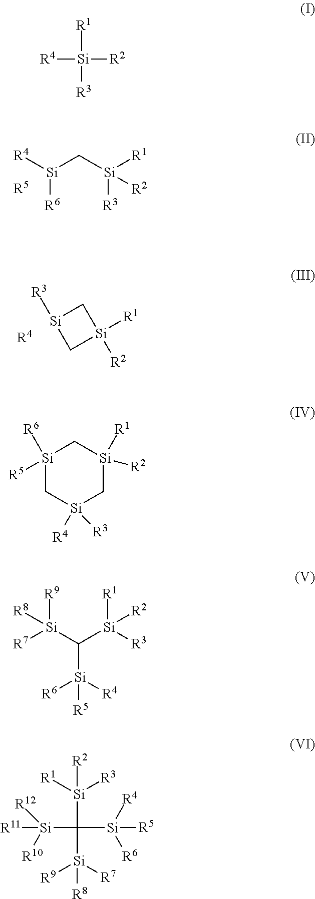
wherein R¹, R², R³, R⁴, R⁵, R⁶, R⁷, wherein R¹, R², R³, R⁴, R⁵, R⁶, R⁷, R⁸, R⁹, R¹⁰, R¹¹, and R¹² are independently selected from hydrogen (H), substituted or unsubstituted linear alkyl, substituted or unsubstituted branched alkyl, substituted or unsubstituted linear alkoxy, substituted or unsubstituted branched alkoxy, and substituted or unsubstituted vinyl, substituted or unsubstituted linear alkyl amines, and substituted or unsubstituted branched alkyl amines;
purging the semiconductor substrate of the silicon precursor;
exposing the substrate to a plasma of a combination of one or more of argon (Ar), hydrogen (H₂), helium (He), nitrogen (N₂), ammonia (NH₃), hydrocarbon, and oxygen (O₂) with of an oxidant comprising one or more of an alcohol, a carboxylic acid, an aldehyde, a diol, a phenol, a peroxide, or ozone (O₃) to form the low-κ film on the semiconductor substrate; and
purging the semiconductor substrate of the plasma.

12. The method of claim 11, wherein the plasma is a remote plasma.

13. The method of claim 11, wherein the plasma is a direct plasma.

14. The method of claim 11, wherein the oxidant comprises ozone (O₃) or a general formulae (A), (B), (C), (D), (E), and (F): 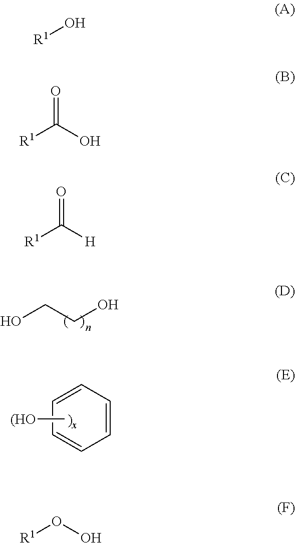
wherein R¹ is independently selected from hydrogen (H), substituted or unsubstituted linear alkyl, substituted or unsubstituted branched alkyl, substituted or unsubstituted linear alkoxy, substituted or unsubstituted branched alkoxy, substituted or unsubstituted vinyl, substituted or unsubstituted linear alkyl amines, and substituted or unsubstituted branched alkyl amines, n is an integer from −1 to 6, and x is an integer from 1 to 3.

15. The method of claim 11, wherein the low-κ film comprises one or more of silicon oxycarbide (SiCO), silicon oxycarbonitride (SiCON), silicon carbonitride (SiCN), silicon carbide (SiC), silicon oxide (SiOx), silicon oxynitride (SiON), and silicon nitride (SiN).

16. The method of claim 11, wherein the low-κ film has a K-value of greater than 3.5.

17. The method of claim 11, wherein the low-κ film has a conformality of greater than 90%.

18. The method of claim 11, wherein purging the semiconductor substrate comprises flowing a purge gas over the semiconductor substrate.

19. The method of claim 18, wherein the purge gas is selected from one or more of argon (Ar), nitrogen (N₂), or helium (He).

20. The method of claim 11, wherein the low-κ film has a thickness greater than about 0.1 nm.
